(19) United States
(12) Patent Application Publication
(10) Pub. No.: US 2018/0100899 A1
(43) Pub. Date: Apr. 12, 2018

(54) STATE-OF-CHARGE INDICATION SYSTEM AND RELATED METHOD

(71) Applicant: MEDIATEK INC., Hsin-Chu (TW)

(72) Inventors: Jui-Chi Wu, Taichung City (TW); Jia-You Chuang, Hsinchu County (TW)

(21) Appl. No.: 15/287,745

(22) Filed: Oct. 7, 2016

(51) Int. Cl. G01R 31/36

(52) U.S. Cl. CPC G01R 31/3651; G01R 31/3675; G01R 31/3637

(57) ABSTRACT

A state-of-charge (SOC) indication method includes: determining estimated values of a SOC of a battery cell according to at least information regarding a characteristics measurement of the battery cell; performing a smooth and monotonic processing on the estimated values of the SOC to process unusual change in the estimated values, so as to generate processed values of the SOC; remapping the processed values of the SOC according to a remapping threshold setting to obtain remapped values of the SOC; and indicating the SOC of the battery cell with the remapped values.

### BACKGROUND

The present invention relates to battery state-of-charge (SOC) estimation, and more particularly to a method and system for estimating the SOC of the battery, processing results of SOC estimation, and indicating the battery SOC.

Batteries are used in numerous applications, such as portable devices, smartphones, laptops, tablets and so on. It is important for the user to know an amount of available energy remaining in a battery of a battery-powered device and when the battery needs to be charged or replaced, so as to avoid the battery running out of energy and thus the battery-powered device being inoperable.

An amount of charges remained in the battery is usually expressed by state of charge (SOC), which is in form of a percentage of a maximum battery capacity. Usually, 100% SOC state means a battery cell is fully charged, while 0% SOC state means the battery cell is fully discharged. In order to timely indicate the SOC to the user, the battery-powered device needs to accurately estimate the SOC of the battery. However, the SOC of a battery is dependent on a variety of factors, such as, inherent chemical characteristics of the battery and characteristics of the battery-powered device, as well as operating conditions of the battery. Even though there are plenty of algorithms provided to improve the estimation of the SOC, there are some conditions leading to a poor user experience on the usage of the battery-powered device.

### SUMMARY

In order to improve the user experience on the usage of the battery-powered device, the present invention provides several processing that can be performed on estimated values of the SOC before the estimated values are presented to the user.

Specifically, the present invention determines the estimated values of the SOC based on voltage and/or current measurements of the battery in conjunction with several different types of compensations, such as aging compensation, temperature compensation, loading compensation and sleep mode voltage compensation, such that accurate estimated values of the SOC could be obtained. After the estimated values of the SOC are obtained, a smooth and monotonic processing will be performed on the estimated values to fix unusual changes in the estimated values since the unusual change in the estimated values may provide the poor user experience if presented to the user without being processed. After the smooth and monotonic processing, a remapping processing is then performed upon the processed estimated values, which remaps the processed estimated value when the SOC is close to a full charge state or an empty state. The remapping processing is intended to improve the user experience regarding a long charging time of the constant-current controlled charging and a short usage time in low battery power state.

According to one embodiment of the present invention, a state-of-charge (SOC) indication method is provided. The SOC indication method comprises: determining estimated values of a SOC of a battery cell according to at least information regarding a characteristics measurement of the battery cell; performing a smooth and monotonic processing on the estimated values of the SOC to process an unusual change in the estimate values, so as to obtain processed values of the SOC; remapping the processed values of the SOC according to a remapping threshold setting to obtain remapped values of the SOC; and indicating the SOC of the battery cell with the remapped values of the SOC.

According to one embodiment of the present invention a state-of-charge (SOC) indication system is provided, which comprises: an SOC estimation circuit, a smooth and monotonic processing circuit, a remapping processing circuit and an indication circuit. The SOC estimation circuit is arranged to determine estimated values of a SOC of a battery cell according to at least information regarding a characteristics measurement of the battery cell. The smooth and monotonic processing circuit is coupled to the SOC estimation circuit, and arranged to perform a smooth and monotonic processing on the estimated values of the SOC to process an unusual change in the estimated values, so as to obtain processed values of the SOC. The remapping processing circuit is coupled to the smooth and monotonic processing circuit, and arranged to remap the processed values of the SOC according to a remapping threshold setting to obtain remapped values of the SOC. The indication circuit is coupled to the remapping processing circuit, and arranged to indicate the SOC of the battery cell with the remapped values of the SOC.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a configuration of an SOC indication system according to one embodiment of the present invention.

FIG. 2 illustrates a block diagram of an SOC indication system according to one embodiment of the present invention.

FIG. 3 illustrates a block diagram of the SOC estimation block of the SOC indication system according to a first embodiment of the present invention.

FIG. 4 illustrates a block diagram of the SOC estimation block of the SOC indication system according to a second embodiment of the present invention.

FIG. 5 illustrates relationship between processed values and estimated values during a discharging state of the battery cell.

FIG. 6 illustrates relationship between processed values and estimated values during a charging state of the battery cell.

FIG. 7 illustrates relationship between remapped values and processed values.

FIG. 8 illustrates a work flow of the SOC indication system according to one embodiment of the present invention.

### DETAILED DESCRIPTION

Certain terms are used throughout the following descriptions and claims to refer to particular system components. As one skilled in the art will appreciate, manufacturers may refer to a component by different names. This document does not intend to distinguish between components that differ in name but not differ in functionality. In the following discussion and in the claims, the terms “include”, “including”, “comprise”, and “comprising” are used in an open-ended fashion, and thus should be interpreted to mean “including, but not limited to . . . ” The terms “couple” and “coupled” are intended to mean either an indirect or a direct electrical connection. Thus, if a first device couples to a second device, that connection may be through a direct electrical connection, or through an indirect electrical connection via other devices and connections.

Reference throughout this specification to “one embodiment”, “an embodiment”, “one example” or “an example” means that a particular feature, structure or characteristic described in connection with the embodiment or example is included in at least one embodiment of the present embodiments. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or sub-combinations in one or more embodiments or examples.

Embodiments of the present invention may be implemented as an apparatus, method, or computer program product. Accordingly, these embodiments may be implemented with entire hardware combinations, entire software combinations, such as software, firmware, instructions, micro codes, or mixing of software and hardware combinations. In the following, all the possible combinations are referred to as a “block” or “system.”

Flowcharts in the drawings illustrate the architecture, functionality, and operation of possible implementations of systems, methods, and computer program products according to various embodiments of the present embodiments. Each block in the flowchart may represent a module, segment, or portion of code, which comprises one or more executable instructions for implementing the specified logical functions. It will also be noted that each block of flowchart illustrations may be implemented by special/general purpose hardware-based systems that perform the specified functions or acts, or combinations of special purpose hardware and computer instructions. These executable instructions may be stored in a computer-readable medium that can direct a computer or other programmable data processing apparatus to function in a particular manner.

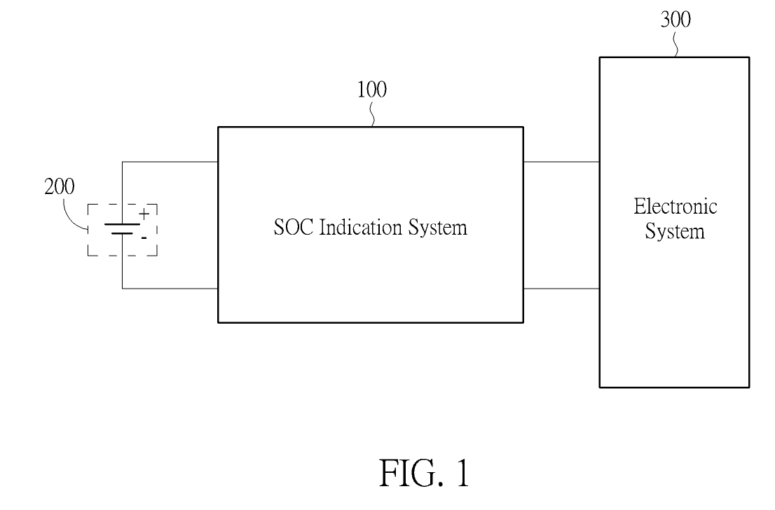

FIG. 1 illustrates a state-of-charge (SOC) indication system 100 according to one embodiment of the present invention. The SOC indication system 100 is basically used to estimate an SOC of a battery cell 200 and accordingly indicates it. In a typical configuration, the battery cell 200 is connected to power an electronic system 300 that the SOC indication system 100 may reside. According to various embodiments of the present invention, the SOC indication system 100 could be partially or entirely implemented with a battery fuel gauge of the electronic system 300.

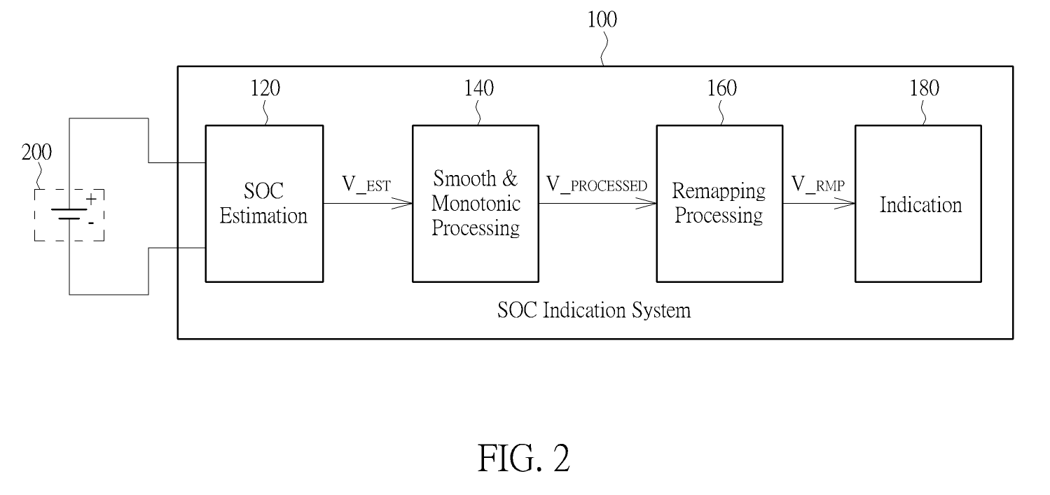

According to an embodiment illustrated by FIG. 2, the SOC indication system 100 comprises an SOC estimation block 120, a smooth and monotonic processing block 140, and a remapping processing block 160. The SOC estimation block 120 is arranged to determine estimated values V_{—EST} of the SOC of the battery cell 200 according to information regarding at least one characteristics measurement of the battery cell 200. The smooth and monotonic processing block 140 generates processed values V_{—PROCESSED} based on smooth and/or monotonic processing on the estimated values V_{—EST}. The smooth and/or monotonic processing is intended to fix unusual changes in the estimated values V_{—EST}. Then, according to the processed values V_{—PROCESSED} of the SOC, the remapping processing block 160 determines remapped value V_{—RMP} of the SOC, which is generated by remapping the processed values V_{—PROCESSED} of the SOC to predetermined bounds once the processed values V_{—PROCESSED} are found higher or lower than predetermined thresholds. The remapped value V_{—RMP} of the SOC will be then presented to the user through an indication block 180 (which could be implemented with a user interface of the electronic system 300).

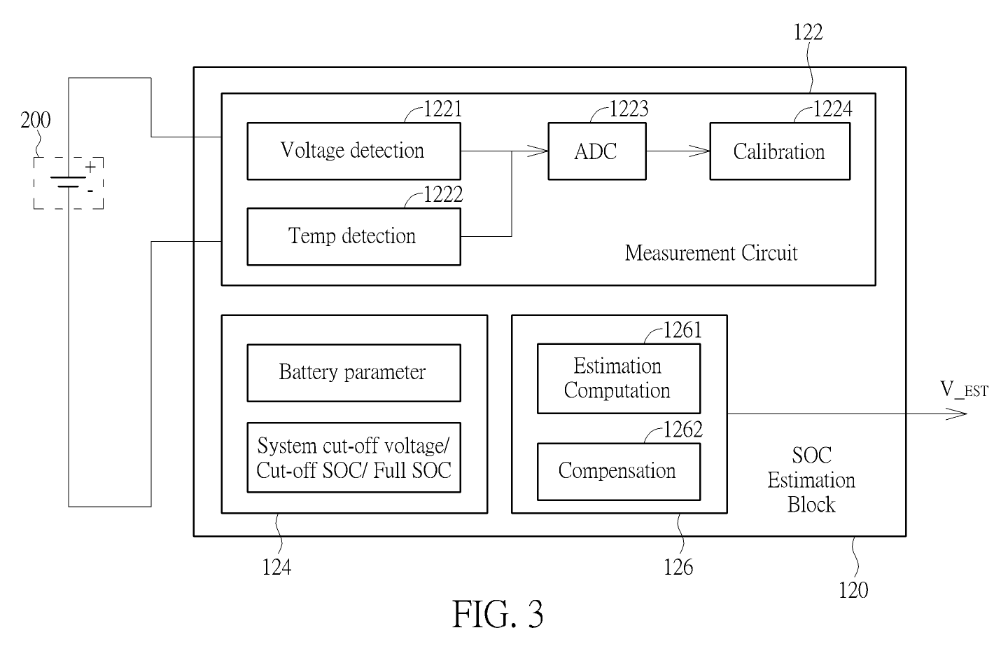

FIG. 3 illustrates a configuration of the SOC estimation block 120 according to one embodiment of the present invention. In this embodiment, the SOC estimation block 120 comprises a measurement circuit 122, an information storage circuit 124 (which can be a part of a memory device) and a computation block 126. The measurement circuit 122 comprises a voltage detection circuit 1221 and a temperature detection circuit 1222, which are utilized for measuring a voltage and a temperature of the battery cell 200, respectively. Signals measured by the voltage detection circuit 1221 and the temperature detection circuit 1222 could be converted into digital form by an analog-to-digital converter (ADC) 1223 and then calibrated by a calibration circuit 1224 to cancel an offset that may be caused by the voltage detection circuit 1221, the temperature detection circuit 1222 and/or the ADC 1223. An estimation computation block 1261 in the estimation block 126 could determine the SOC based on the information provided by the measurement circuit 122 and the information storage circuit 124. Preferably, the determination of the SOC is based on a coulomb counting method. The estimation computation block 1261 refers to battery parameters (which may be further compensated by temperature compensation before referred to) stored in the information storage circuit 124 and the measured voltage to determine an initial state of the SOC. Then, the estimation computation block 1261 determines an average current flowing into/out of the battery cell 200 based on the measured voltage of the battery cell 200 according to specific algorithms. Accordingly, the estimation computation block 1261 integrates the average current over a time period to determine a relative change of the SOC. Combined the initial state and the relative change of the SOC, the estimation computation block 1261 could determine an instant state of the SOC for the battery cell 200.

During SOC estimation computation, a compensation block 1262 in the estimation block 126 could compensate the computation of the SOC performed by the estimation computation block 1261. Specifically, the values computed by the estimation computation block 1261 could not reflect the “actual” SOC of the battery cell 200 due to a variety of factors, such as battery aging, battery temperature, or battery loading. Therefore, several compensations will be performed by the compensation block 1262 to get accurate SOC estimations.

With respect to temperature compensation, the compensation block 1262 could read and adaptively correct the battery parameters stored in the information storage circuit 124. The battery parameters may include ZCV, depth of discharge (DOD), internal resistance, and maximum available capacity, with respect to different temperatures. In order to save the size of the information storage circuit 124, only those battery parameters corresponding to specific temperatures are stored. The compensation block 1262 could perform interpolation upon the battery parameters corresponding to certain temperatures so as to derive the battery parameters corresponding to a temperature that is instantly measured from the battery cell 200. According to the measured temperature and the battery parameters natively from the information storage circuit 124 or by the interpolation, the compensation block 1262 could correct the battery parameters that will be later used in the computation of the SOC estimation, such that the estimation computation block 1261 could computes the SOC more accurately.

With respect to loading compensation, the compensation block 1262 could read information regarding maximum available capacity of the battery cell 200 from the information storage circuit 124. According to such information in conjunction with the average discharge current of the battery cell 200, the compensation block 1262 could determine a loading factor which reflects the instant loading of the battery cell 200, and thereby compensating the computation of SOC based on the loading factor. With respect to aging compensation, the compensation block 1262 calculates errors of the internal resistance of the battery cell 200 between the stored parameters and the actual condition. The compensation block 1262 accordingly determines an aging factor. The estimation computation block 1261 could compute the SOC estimation based on the aging factor. The compensation block 1262 also performs a sleep mode voltage compensation, which calibrate the initial state of the SOC according to a voltage of the battery cell 200 that is measured when the electronic system 300 stays in a sleep mode for a certain period.

The information storage circuit 124 further stores a system cut-off voltage, a battery cut-off voltage, and/or a battery full voltage. Such information is also readable to the estimation computation block 1261 and the compensation block 1262 while computing the SOC and compensates the computation of the SOC estimation.

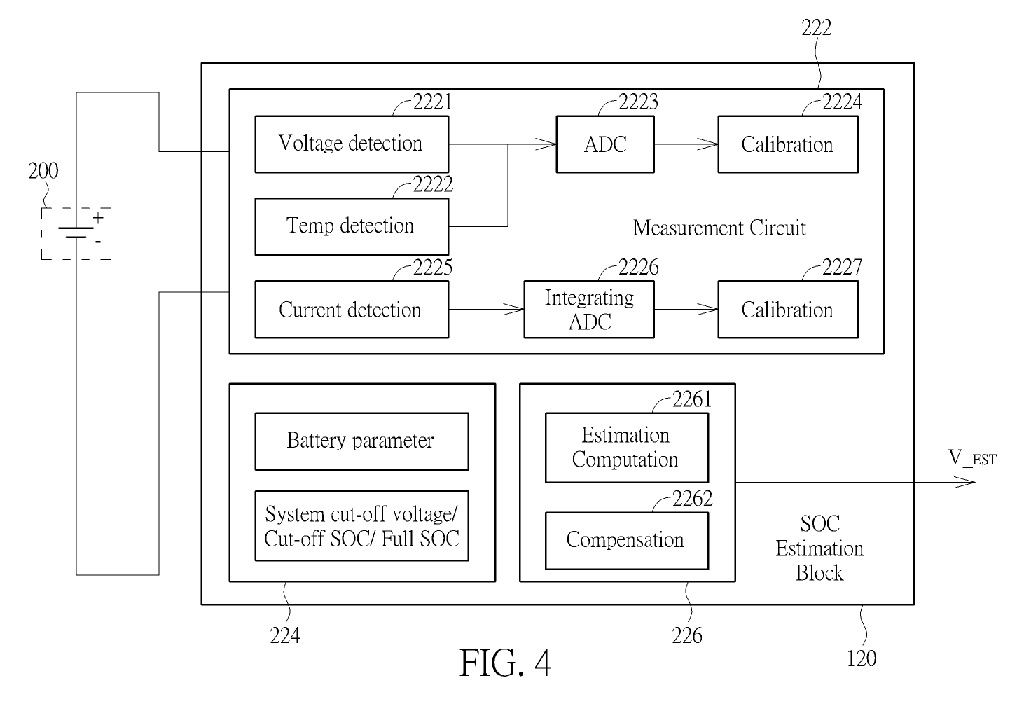

FIG. 4 illustrates another configuration of the SOC estimation block 120 according to another embodiment of the present invention. A major difference between embodiments in FIG. 3 and FIG. 4 is the configuration of the measurement circuit. In a measurement circuit 222 illustrated by FIG. 4, a current detection circuit 2225 and an integrating converter 2226 are further included therein for performing a coulomb counting computation to estimate the relative change of the SOC. Additionally, a calibration circuit 2227 that follows the integrating converter 2226 could be used to calibrate the offset generated in the coulomb counting computation. An estimation computation block 2261 in an estimation block 226 could compute the SOC according to the information provided by the measurement circuit 222, including the voltage and temperature measurements of the battery cell 200 and results of the coulomb counting computation. Similarly, the compensation block 2262 in the estimation block 226 could perform compensation on the SOC estimation performed by the estimation computation block 2261 in the manners as mentioned above. Further, the information storage circuit 224 also store information regarding battery parameters as mentioned in the information storage circuit 124.

Afterwards, the SOC estimation block 120 could provide estimated values of the SOC of the battery cell 200 to the following stages, the smooth and monotonic processing block 140 and the remapping processing block 160.

The smooth and monotonic block 140 can handle unusual changes in the estimated values V_{—EST}. There are two types of the unusual changes that may occur in the estimated values V_{—EST}. A first one of them is the inconsistent change. In certain conditions, when the battery cell 200 is being charged, the estimated values V_{—EST} of the SOC may reflect a decrease of the SOC. Alternatively, when the battery cell 200 is being discharged, the estimated values of the SOC may reflect an increase of the SOC. Such changes of the SOC are inconsistent with the charging state of the battery cell 200, which makes the user feel strange. The user may think there is a functional or quality issue on the battery cell 200 or a charger system of the electronic system 300.

The inconsistent change may be caused by a significant change in the temperature of the battery cell 200. Typically, the temperature of the battery cell 200 affects its maximum battery capacity. When the temperature is higher, the maximum battery capacity is higher. As the SOC estimation is affected by the maximum battery capacity of the battery cell 200, when the change of the temperature is significantly larger than the change of the “actual” SOC of the battery cell 200, the change of the estimated values may be inconsistent with the charging state of the battery cell 200. In order to fix such inconsistency, the SOC indication system 100 utilizes the smooth and monotonic processing block 140 to process the estimated values V_{—EST} of the SOC.

At first, the smooth and monotonic processing block 140 detects the charging state of the battery cell 200. If it is detected the battery cell 200 is in a discharging state, the smooth and monotonic processing block 140 generates the processed values V_{—PROCESSED} with respect to the estimated values V_{—EST} not to reflect an increase of estimated values V_{—EST}. Alternatively, if it is detected the battery cell 200 is in a charging state, the smooth and monotonic processing block 140 generates the processed values V_{—PROCESSED} with respect to the estimated values V_{—EST} not to reflect a decrease of the estimated values V_{—EST}. That is, the processed values V_{—PROCESSED} will not reflect the change of the estimated values V_{—EST} that is “inconsistent” with the charging state of the battery cell 200.

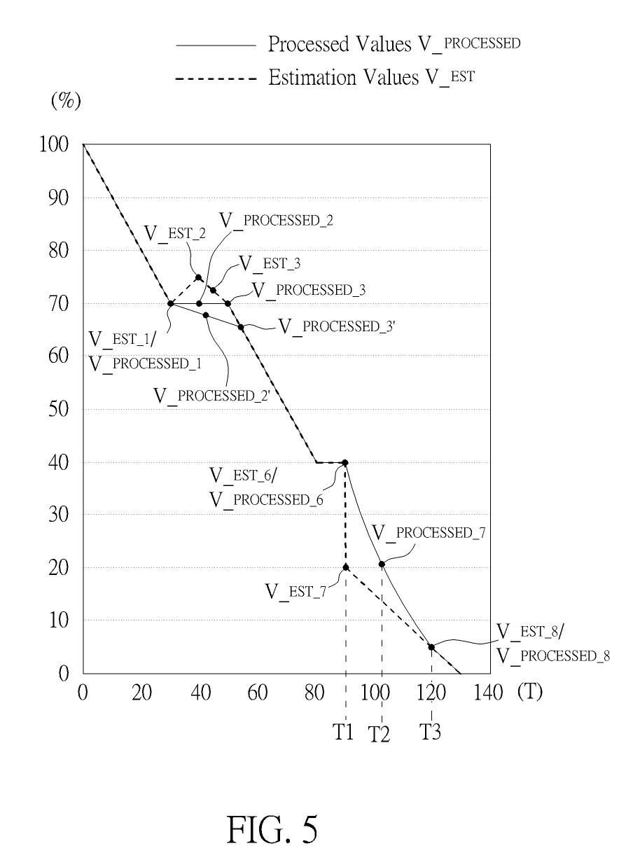

Please refer to FIG. 5 for further details of generating the processed values V_{—PROCESSED}. FIG. 5 illustrates relationship between the processed values V_{—PROCESSED} (represented by a solid line) and the estimated values V_{—EST} (represented by a dash line) during a discharging period of the battery cell 200. As shown, the estimated values V_{—EST}_{_}₁ and V_{—EST}_{_}₂ reflect an increase of the SOC while the battery cell 200 is being discharged. At this time, the smooth and monotonic processing block 140 generates processed values V_{—PROCESSED}, such as V_{—PROCESSED}_{_}₁ and V_{—PROCESSED}_{_}₂ that remain the same in order not to reflect the increase. In addition, although the estimated value V_{—EST}_{_}₃ does not reflect an increase with respect to the estimated value V_{—EST}_{_}₂, the estimated value V_{—EST}_{_}₃ still reflect an increase with respect to the estimated value V_{—EST}_{_}₁, however. Therefore, the processed value V_{—PROCESSED}_{_}₃ with respect to the estimated value V_{—EST}_{_}₃ still remains the same as V_{—PROCESSED}_{_}₁ and V_{—PROCESSED}_{_}₂ in order not to reflect the increase of the SOC. That is to say, once the estimated values V_{—EST} reflect an increase of the SOC within the discharging period of the battery cell 200, the smooth and monotonic processing block 140 will not allow the processed values V_{—PROCESSED} corresponding to the increasing estimated values V_{—EST} to reflect the increase of the SOC.

In another embodiment, the smooth and monotonic processing block 140 may generate the processed values V_{—PROCESSED} reflecting a decrease of the SOC as long as the estimated values V_{—EST} reflect an increase of the SOC within the discharging period of the battery cell 200. Please refer to FIG. 5 again. In response to the increasing estimated values V_{—EST}_{_}₁, V_{—EST}_{_}₂ and V_{—EST}_{_}₃, the smooth and monotonic processing block 140 may generate the processed values V_{—PROCESSED}_{_}₁′, V_{—PROCESSED}_{_}₂′ and V_{—PROCESSED}_{_}₃′ to reflect a slight decrease of the SOC even if the estimated values V_{—EST}_{_}₁, V_{—EST}_{_}₂ and V_{—EST}_{_}₃ reflect the increase of the SOC. In can be seen from FIG. 5 that the processed value V_{—PROCESSED}_{_}₃′ and the estimated value V_{—EST}_{_}₃ have an error therebetween. Such error will be later corrected by the smooth and monotonic processing block 140 by “slowing down” the change of the processed value V_{—PROCESSED} such that the processed value V_{—PROCESSED} is able to keep up with the estimated value V_{—EST} at a later time.

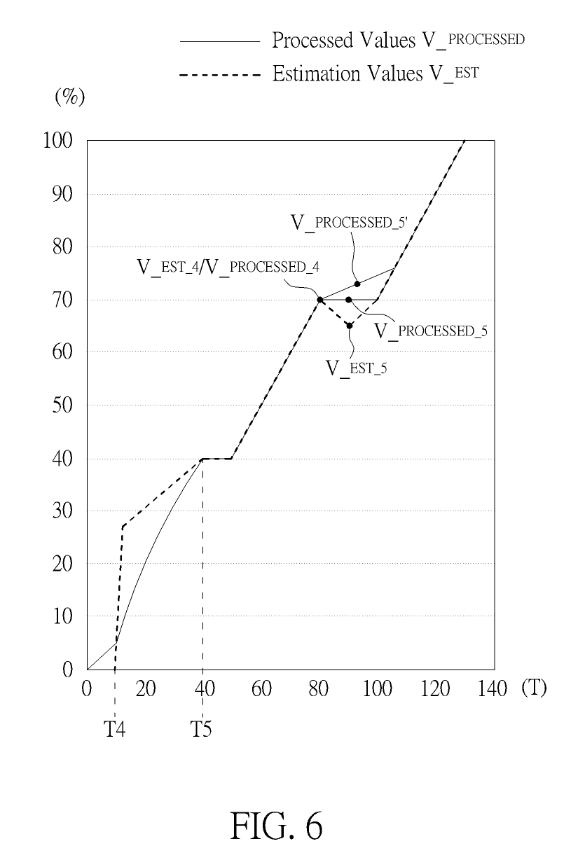

FIG. 6 illustrates relationship between the processed values V_{—PROCESSED} (represented by a solid line) and the estimated values V_{—EST} (represented by a dash line) during a charging period of the battery cell 200. When it is detected the battery cell 200 is in a charging state and a couple of decreasing estimated values V_{—EST}_{_}₄ and V_{—EST}_{_}₅, the smooth and monotonic processing block 140 generates processed values, such as V_{—PROCESSED}_{_}₄ and V_{—PROCESSED}_{_}₅ that remain the same in order not to reflect the decrease. That is to say, once the estimated values V_{—EST} reflect a decrease of the SOC within the charging period of the battery cell 200, the smooth and monotonic processing block 140 will not allow the processed values V_{—PROCESSED} to reflect the decrease of the SOC. In another embodiment, the smooth and monotonic processing block 140 may generate the processed values V_{—PROCESSED} reflecting an increase of the SOC as long as the estimated values V_{—EST} reflect a decrease of the SOC within the charging period of the battery cell 200. Please refer to FIG. 6 again. In response to the decreasing estimated values V_{—EST}_{_}₄ and V_{—EST}_{_}₅, the smooth and monotonic processing block 140 may generate the processed values V_{—PROCESSED}_{_}₄′ and V_{—PROCESSED}_{_}₅′ to reflect a slight increase of the SOC even if the estimated values V_{—EST}_{_}₄ and V_{—EST}_{_}₅ reflect the decrease of the SOC. In can be seen from FIG. 6 that after the processed value V_{—PROCESSED}_{_}₅′, there is an obvious error between the estimated value V_{—EST} and the processed value V_{—PROCESSED}. Such error will be later corrected by the smooth and monotonic processing block 140 by “slowing down” the change of the processed value V_{—PROCESSED} such that the processed value V_{—PROCESSED} is able to keep up with the estimated value V_{—EST} at a later time.

Through the smooth and monotonic processing block 140, the inconsistent change in the estimated values can be fixed by either remaining the processed values V_{—PROCESSED} with respect to the “inconsistent” estimated values V_{—EST} unchanged or reflecting a change of the SOC that is consistent with the charging state of the battery cell 200.

A second type of unusual changes is a sudden change, which may result from the inaccurate SOC estimation. That is, the SOC estimation is affected by the chemical characteristics of the battery cell 200, the characteristics of electronic system 300, and the operating condition of the battery cell 300. If the SOC estimation algorithms cannot properly take all of these factors into consideration, the SOC estimation will be inaccurate, thereby leading a sudden change of the estimated value V_{—EST}. Presenting the sudden change of the SOC to the user also brings the poor user experience. It is necessary to smooth out the sudden change of the estimated values V_{—EST} of the SOC before it is presented to user.

For the sudden change, the smooth and monotonic processing block 140 detects a rate of change of the estimated values V_{—EST} to determine whether there is a sudden change in the estimated values V_{—EST}. Please refer to FIG. 5 for further details. As shown, at time T1, the estimated values V_{—EST} have a sudden drop from the estimated value V_{—EST}_{_}6 to the estimated value V_{—EST}_{_}7. Therefore, the smooth and monotonic processing block 140 needs to smooth out the sudden drop.

Basically, the smooth and monotonic processing block 140 controls the processed values V_{—PROCESSED} not to reflect the estimated value V_{—EST} immediately but to keep up with the estimated value V_{—EST} smoothly and gently when it is found that the rate of change of the estimated values V_{—EST} is too high (e.g., the sudden drop at time T1) or higher than a predetermined threshold. For example, in response to the estimated value V_{—EST}_{_}7, the processed values V_{—PROCESSED} generated by the smooth and monotonic processing block 140 around time T1 does not reflect the estimated value V_{—EST}_{_}7 faithfully. Until time T2, the processed value V_{—PROCESSED}_{_}7 generated by the smooth and monotonic processing block 140 is closer to estimated value V_{—EST}_{_}₇.

With respect to the sudden change, the smooth and monotonic processing block 140 determines the rate of change of corresponding processed value V_{—PROCESSED} according to an overall consideration on the instant estimated value V_{—EST}, the rate of the change of the estimated values V_{—EST}, the maximum battery capacity, the temperature, and the loading/current of the battery cell 200, thereby smoothly keep up with the estimated values V_{—EST}.

For example, if the estimated value V_{—EST} is low, which means the battery cell 200 may run out of energy soon, the smooth and monotonic processing block 140 needs to control the processed values V_{—PROCESSED} to keep up with the estimated value V_{—EST} faster; otherwise, the battery cell 200 may run out of energy while the processed value V_{—PROCESSED} is still not too low. Additionally, When the current/loading of the battery cell 200 is large, the smooth and monotonic processing block 140 needs to control the rate of change of the processed values V_{—PROCESSED} to be high; otherwise, the processed values V_{—PROCESSED} may never keep up with the estimated value V_{—EST}.

As illustrated in FIG. 5, after smoothed by the smooth and monotonic processing block 140, the processed values V_{—PROCESSED}_{_}6, V_{—PROCESSED}_{_}7 and V_{—PROCESSED}_{_}8 have an overall smoother change than the change of the estimated values V_{—EST}_{_}6, V_{—EST}_{_}7 and V_{—EST}_{_}8 from the time T1 to T3. A similar case regarding the sudden change and corresponding processing during the charging period of the battery cell 200 are illustrated with respect to time T4 to T5 in FIG. 6. Repeated explanations are omitted here for the sake of brevity.

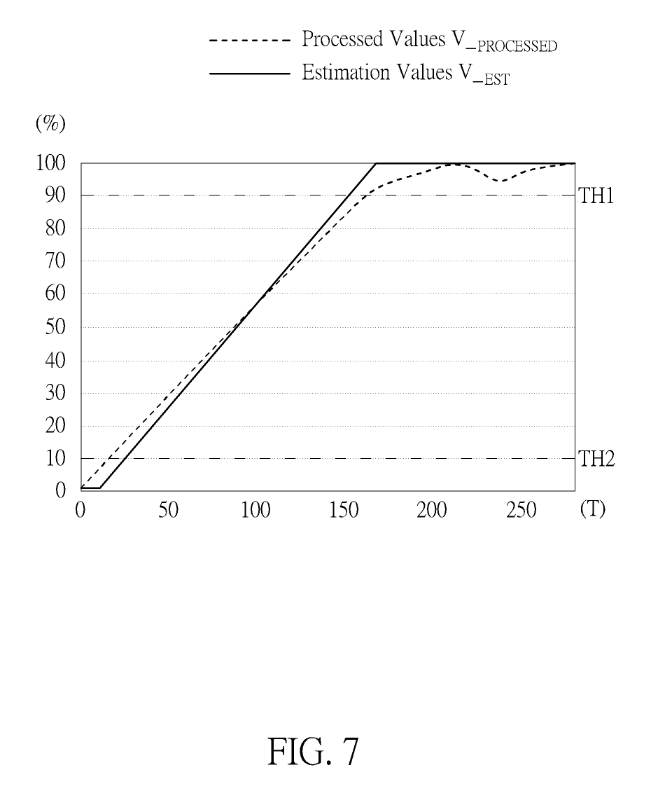

Please refer to FIG. 7 for understanding how the remapping processing block 160 works. When charging the battery cell 200, a charging system (not shown) that resides in the electronic system 300 could utilize and switch between a constant-current (CC) controlled charge method and a constant-voltage (CV) controlled charge method to charge the battery cell 200. Compared to the CC controlled charge method, the CV controlled charge method is quite slow in leveling up the SOC of the battery cell 200. That is, the user may experience a short period when the battery cell 200 is charged with the CC controlled charge method while experience a relative long period when the battery cell 200 is charged with the CV controlled charge method. This also confuses the user and brings a poor user experience. Hence, the remapping processing block 160 monitors the processed values V_{—PROCESSED} of the SOC. Once it is detected the processed values V_{—PROCESSED} are higher than a predetermined upper threshold TH1, such as 90% SOC (just for explanatory purposes), the remapping processing block 160 remaps the processed values V_{—PROCESSED} to a upper bound UB, such as 100% SOC. Accordingly, the SOC indication system 100 indicates the SOC of the battery cell 200 with 100% through the indication block 180.

On the other hand, when the battery cell 200 is close to the empty state, once hardware components (e.g. multiple cores of a central processing unit or a graphic processor) of the electronic system 300 draws a large amount of current from the battery cell 200, a system cut-off voltage may be suddenly reached due to the existence of the internal resistance of the battery cell 200. The system cut-off voltage means a minimum voltage for operating all the hardware components in the electronic system 300. If the voltage provided by the battery cell 200 is lower than the system cut-off voltage, the electronic system 300 needs to be shut down to protect these hardware components.

For example, if the SOC of the battery cell 200 is only 10% (or lower), drawing the large amount of the current at this moment may cause the voltage provided by the battery cell 200 to reach the system cut-off voltage. As a result, the electronic system 300 needs to be shut down. However, the user will feel strange because it is too fast from the 10% SOC to shut down the electronic system 300. Hence, when the remapping processing block 160 detects the processed values V_{—PROCESSED} is lower than a predetermined lower threshold TH2, such as 10% SOC (just for explanatory purposes), the remapping processing block 160 remaps the processed values V_{—PROCESSED} to a lower bound LB, such as 1% SOC ((just for explanatory purposes)). Accordingly, the SOC indication system 100 indicates the SOC of the battery cell 200 with 1% through the indication block 180. Indicating the SOC with 1% when the battery cell 200 only has a few of energy, the user will not feel so strange if the electronic system 300 is suddenly shut down.

Another problem is that the user may also feel strange when the SOC remain at 1% for too long. Therefore, a period of time in which the SOC remains at 1% is also adjustable. The remapping processing block 160 could determine a time of period for keeping the SOC at 1%. When the time of period expires, the electronic system 300 will be notified to shut down no matter what the SOC of the battery cell 200 is.

Please note that the above-mentioned values regarding the predetermined upper/lower thresholds (e.g. 90% and 10%) and the upper and lower bounds (e.g. 100% and 1%) that the processed values V_{—PROCESSED} are remapped to are just for explanatory purposes. According to various embodiments of the present invention, the above-mentioned values are adjustable. For example, the remapping processing block 160 may have an upper threshold of 95% SOC, only when the processed values V_{—PROCESSED} is greater than 95% SOC, they are remapped to 100%. Also, the remapping processing block 160 may have a lower threshold of 5% SOC, only when the processed values V_{—PROCESSED} is lower than 5% SOC, they are remapped to 1% SOC.

If the processed value V_{—PROCESSED} of the SOC is lower than the upper threshold TH1 and higher than the lower threshold TH2, they will be remapped according to a scaling factor. That is, the processed values V_{—PROCESSED} between 10%-90% SOC will be remapped to values in the range from 1%-100% SOC. In according with one embodiment, assuming that the processed value is X, the remapped value Y can be obtained by:

(X−TH1)/(TH1−TH2)=(Y−LB)/(UB−LB)

After remapped, once the estimated value V_{—EST} of the SOC drops below the upper threshold TH1 or rises beyond the lower threshold TH2, the SOC indication system 100 will not indicate the SOC with the estimated values below or beyond the thresholds immediately, the smooth and monotonic processing block 140 will control the processed values V_{—PROCESSED} not keep up with the estimated value V_{—EST} immediately. That is, the smooth and monotonic processing block 140 controls the processed values V_{—PROCESSED} to keep up with the estimated value V_{—EST} smoothly according to an overall consideration on the rate of the change of the estimated values V_{EST}, the maximum battery capacity, the temperature, and the loading/current on the battery cell 200.

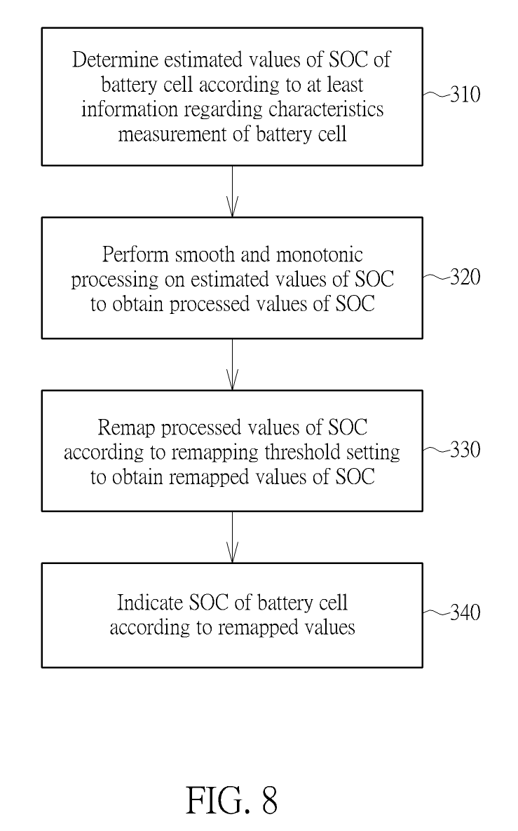

FIG. 8 illustrates a work flow of the SOC indication system 100 according to one embodiment of the present invention. At first, it is determined in step 310 estimated values of a SOC of the battery cell 200 according to at least information regarding a characteristics measurement of the battery cell 200. The information includes that obtained from operations of the measurement circuit 122/222. Also, compensations may be applied in step 310 for accurate estimated values. After the estimated values of the SOC are determined in step 310, the work flow goes to step 320, in which a smooth and monotonic processing is performed by the smooth and monotonic processing block 140 to process the unusual change in the estimated values, thereby obtaining processed values of the SOC, which comprises hiding the inconsistent change and smoothing out the sudden change of the estimated values. After step 320, the flow goes to step 330, in which the processed values of the SOC is remapped by the remapping processing block 160 according to a remapping threshold setting, thereby obtaining remapped values of the SOC. In this step, when the processed value of the SOC is close to the full charge state, the processed value is remapped to the value of the full SOC (i.e., 100%). Additionally, when the processed value of the SOC is close to the empty state of the SOC, the processed value is remapped to the value of a lower bound (e.g. 1%). Once the remapped values are obtained, the flow goes to step 340, indicating the SOC with the remapped values through the indication block 180.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A state-of-charge (SOC) indication method, comprising:
determining estimated values of a SOC of a battery cell according to at least information regarding a characteristics measurement of the battery cell;
performing a smooth and monotonic processing on the estimated values of the SOC to process an unusual change in the estimated values, so as to generate processed values of the SOC;
remapping the processed values of the SOC according to a remapping threshold setting to obtain remapped values of the SOC; and
indicating the SOC of the battery cell with the remapped values of the SOC.

2. The SOC indication method of claim 1, wherein the step of determining the estimated values of the SOC comprises:
measuring a voltage of the battery cell; and
determining the estimated values of the SOC according to the measured voltage.

3. The SOC indication method of claim 2, wherein the step of determining the estimated values of the SOC further comprises:
measuring a current that have flown through the battery cell;
integrating the current that have flown through the battery cell over a period of time to obtain a charge change amount; and
determining the estimated values of the SOC according to the measured voltage and the charge change amount.

4. The SOC indication method of claim 1, wherein the step of determining the estimated values of the SOC comprises:
determining the estimated values of the SOC according to the information regarding the characteristics measurement of the battery cell and at least one estimation compensation.

5. The SOC indication method of claim 4, wherein the estimation compensation includes at least one of battery aging compensation, battery temperature compensation, battery loading compensation and sleep mode voltage compensation.

6. The SOC indication method of claim 1, wherein the step of performing the smooth and monotonic processing on the estimated values to process the unusual change comprises:
determining whether there is a sudden change in the estimated values; and
controlling the processed values not to keep up with the corresponding estimated values immediately when the sudden change is detected.

7. The SOC indication method of claim 6, wherein the step of controlling the processed values not to keep up with the corresponding estimated values when the sudden change is detected comprises: generating the processed values corresponding to the estimated values having the sudden change according to at least one of the estimated values, a rate of change of the estimated values, a maximum battery capacity, a temperature, and a loading/current on the battery cell, in order not to keep up with the estimated values immediately.

8. The SOC indication method of claim 6, wherein the step of determining whether there is the sudden change in the estimated values comprises:
detecting whether a rate of change of the estimated values is higher than a predetermined threshold to determine whether these is the sudden change.

9. The SOC indication method of claim 1, wherein the step of performing the smooth and monotonic processing on the estimated values to process the unusual change comprises:
detecting a charging state of the battery cell;
when the battery cell is determined as in a discharging state, controlling the processed values corresponding to the estimated values not to reflect an increase of the SOC if the estimated values reflect the increase of the SOC; and
when the battery cell is determined as in a charging state, controlling the processed values corresponding to the estimated values not to reflect a decrease of the SOC if the estimated values reflect the decrease of the SOC.

10. The SOC indication method of claim 9, wherein the step of controlling the processed values corresponding to the estimated values comprises:
controlling the processed values corresponding to the estimated values to remain the same if the estimated values reflect the increase of the SOC in the discharging state; and
controlling the processed values corresponding to the estimated values to remain the same even if the estimated values reflect the decrease of the SOC in the charging state.

11. The SOC indication method of claim 9, wherein the step of controlling the processed values corresponding to the estimated values comprises:
controlling the processed values corresponding to the estimated values to reflect a decrease of the SOC if the estimated values reflect the increase of the SOC in the discharging state; and
controlling the processed values corresponding to the estimated values to reflect an increase of SOC if the estimated values reflect the decrease of the SOC in the charging state.

12. The SOC indication method of claim 9, wherein the step of remapping the processed values of the SOC according to a remapping threshold setting to obtain remapped values comprises:
setting one of the processed values of the SOC as a predetermined upper bound when the one of the processed values is higher than a predetermined upper threshold of the remapping threshold setting;
setting one of the processed values of the SOC as a predetermined lower bound when the one of the processed values is lower than a predetermined lower threshold of the remapping threshold setting; and
mapping one of the processed values to one of values between the predetermined upper bound and the predetermined lower bound when the one of the processed values is between the upper threshold and the lower threshold.

13. The SOC indication method of claim 12, wherein the step of setting the one of the processed values of the SOC as the predetermined lower bound comprises:
determining a period of time; and
setting the one of the processed values of the SOC as the predetermined lower bound only within the period of time.

14. A state-of-charge (SOC) indication system, comprising:
an SOC estimation circuit, arranged to determine estimated values of a SOC of a battery cell according to at least information regarding a characteristics measurement of the battery cell;
a smooth and monotonic processing circuit, coupled to the SOC estimation circuit and arranged to perform a smooth and monotonic processing on the estimated values of the SOC to process an unusual change in the estimated values, so as to obtain processed values of the SOC;
a remapping processing circuit, coupled to the smooth and monotonic processing circuit and arranged to remap the processed values of the SOC according to a remapping threshold setting to obtain remapped values of the SOC; and
an indication circuit, coupled to the remapping circuit and arranged to indicate the SOC of the battery cell with the remapped values of the SOC.

15. The SOC indication system of claim 14, wherein the SOC estimation circuit comprises:
a voltage detection circuit, coupled to the battery cell and arranged to measure a voltage of the battery cell; and
an estimation circuit, coupled to the voltage detection circuit, arranged to determine the estimated values of the SOC of the battery cell according to the measured voltage.

16. The SOC indication system of claim 15, wherein the SOC estimation circuit further comprises:
a current detection circuit coupled to the battery cell and arranged to measure a current that have flown through the battery cell;
an integration circuit, coupled to the current detection circuit and arranged to integrate the current that have flown through the battery cell over a period of time to obtain a charge change amount;
wherein the estimation circuit determines the estimated values of the SOC according to the measured voltage and the charge change amount.

17. The SOC indication system of claim 14, wherein the SOC estimation circuit further comprises a compensation circuit and the SOC estimation circuit determines the estimated values of the SOC according to the information regarding the characteristics measurement of the battery cell and at least one estimation compensation that is performed by the estimation compensation circuit.

18. The SOC indication system of claim 17, wherein the estimation compensation circuit performs at least one of battery aging compensation, battery temperature compensation, battery loading compensation, and sleep mode voltage compensation.

19. The SOC indication system of claim 14, wherein the smooth and monotonic processing circuit determines whether there is a sudden change in the estimated values, and controls the processed values not to keep up with the corresponding estimated values immediately when the sudden change is detected.

20. The SOC indication system of claim 19, wherein the smooth and monotonic processing circuit generates the processed values corresponding to the estimated values having the sudden change according to at least one of the estimated values, a rate of change of the estimated values, a maximum battery capacity, a temperature, and a loading/current on the battery cell, in order not to keep up with the estimated values immediately.

21. The SOC indication system of claim 19, wherein the smooth and monotonic processing circuit detects whether a rate of change of the estimated values is higher than a predetermined threshold to determine whether there is the sudden change.

22. The SOC indication system of claim 14, wherein the smooth and monotonic processing circuit:
detects a charging state of the battery cell;
when the battery cell is determined as in a discharging state, controls the processed values corresponding to the estimated values not to reflect an increase of the SOC if the estimated values reflect the increase of the SOC; and
when the battery cell is determined as in a charging state, controls the processed values corresponding to the estimated values not to reflect a decrease of the SOC if the estimated values reflect the decrease of the SOC.

23. The SOC indication system of claim 22, wherein the smooth and monotonic processing circuit controls the processed values corresponding to the estimated values to remain the same if the estimated values reflect the increase of the SOC in the discharging state, and controls the processed values corresponding to the estimated values to remain the same if the estimated values reflect the decrease of the SOC in the charging state.

24. The SOC indication system of claim 22, wherein the smooth and monotonic processing circuit controls the processed values corresponding to the estimated values to reflect a decrease of the SOC if the estimated values reflect the increase of the SOC in the discharging state, and controls the processed values corresponding to the estimated values to reflect an increase of SOC if the estimated values reflect the decrease of the SOC in the charging state.

25. The SOC indication system of claim 14, wherein the remapping processing circuit:
sets one of the processed values of the SOC as a predetermined upper bound when the one of the processed values is higher than a predetermined upper threshold of the remapping threshold setting;
sets one of the processed values of the SOC as a predetermined lower bound when the one of the processed values is lower than a predetermined lower threshold of the remapping threshold setting; and
maps one of the processed values of the SOC to one of values between the predetermined upper bound and the predetermined lower bound when the one of the processed values is between the upper threshold and the lower threshold.

26. The SOC indication system of claim 25, wherein the remapping processing circuit further determines a period of time, and sets the one of the processed values of the SOC as the predetermined lower bound only within the period of time.
